(19) United States
(12) Patent Application Publication
(10) Pub. No.: US 2025/0324699 A1
(43) Pub. Date: Oct. 16, 2025

(54) METHOD OF LOW-TEMPERATURE N-TYPE SELECTIVE SILICON EPITAXY

(71) Applicant: Applied Materials, Inc., Santa Clara, CA (US)

(72) Inventors: Yi-Chiau HUANG, Fremont, CA (US); Jason JEWELL, Santa Clara, CA (US)

(21) Appl. No.: 18/632,863

(22) Filed: Apr. 11, 2024

(51) Int. Cl. H01L 29/167; H01L 21/02; H01L 21/3065

(52) U.S. Cl. CPC H10D 62/834; H01L 21/02532; H01L 21/02576; H01L 21/3065

(57) ABSTRACT

Semiconductor devices and methods for manufacturing semiconductor devices that include low temperature selective deposition of epitaxial silicon-containing films are provided. The method includes performing a first deposition process, a second deposition process subsequent to the first deposition process, and an etch process. The first deposition process includes forming an n-type doped semiconductor layer including a first n-type dopant on an exposed surface of a substrate. The second deposition process includes forming an n-type doped capping layer on the doped semiconductor layer, the n-type doped capping layer including a second n-type dopant different from the first n-type dopant. The etch process selectively removing an amorphous portion of the n-type doped semiconductor layer and an amorphous portion of the n-type doped capping layer, and leaving an epitaxial portion of the n-type doped semiconductor layer and an epitaxial portion of the n-type doped capping layer.

### BACKGROUND

### Field

The present disclosure generally relates to the field of semiconductor devices and methods for manufacturing semiconductor devices. More particularly, the disclosure relates to low temperature selective deposition of epitaxial silicon-containing films.

### Description of the Related Art

A typical selective epitaxy process involves a deposition reaction and an etch reaction. The deposition reaction causes an epitaxial layer to be formed on monocrystalline surfaces of a substrate and a polycrystalline and/or amorphous layer to be formed on non-monocrystalline surfaces, for example, a patterned dielectric layer deposited atop the substrate. The etch reaction removes the epitaxial layer and the polycrystalline and/or amorphous layer at different rates, providing a net selective process that can result in deposition of an epitaxial material and limited, or no, deposition of a polycrystalline material and/or amorphous material.

As the critical dimensions of devices continue to shrink, methods of selective epitaxial deposition involve lower processing temperatures (e.g., about 500 degrees Celsius or less). Unfortunately, typical etching gases fail to provide a suitable selective window between the epitaxial layer and the polycrystalline and/or amorphous layer at lower processing temperatures. In addition, current cyclic deposition/etch processes can be complex, difficult to maintain, and have low throughput.

For the foregoing reasons, there is a need for selective epitaxial processes that can be performed at lower temperatures.

### SUMMARY

The present disclosure generally relates to the field of semiconductor devices and methods for manufacturing semiconductor devices. More particularly, the disclosure relates to low temperature selective deposition of epitaxial silicon-containing films.

In one aspect, a method of forming a doped semiconductor layer in a semiconductor structure is provided. The method includes performing a first deposition process, a second deposition process subsequent to the first deposition process, and an etch process. The first deposition process includes forming an n-type doped semiconductor layer including a first n-type dopant on an exposed surface of a substrate. The second deposition process includes forming an n-type doped capping layer on the doped semiconductor layer, the n-type doped capping layer including a second n-type dopant different from the first n-type dopant. The etch process selectively removing an amorphous portion of the n-type doped semiconductor layer and an amorphous portion of the n-type doped capping layer, and leaving an epitaxial portion of the n-type doped semiconductor layer and optionally an epitaxial portion of the n-type doped capping layer. The n-type doped semiconductor layer and the n-type doped capping layer comprise silicon.

Implementations may include one or more of the following. The first n-type dopant includes phosphorus. The second n-type dopant includes arsenic, antimony, or both arsenic and antimony. The first deposition process includes flowing a silicon-containing precursor in a processing chamber. The second deposition process includes flowing the silicon-containing precursor and a second n-type dopant source in the processing chamber. The etch process includes flowing an etchant gas and a carrier gas in a processing gas, subsequent to the second deposition process. The etch process includes flowing an etchant gas and a carrier gas in a processing gas, simultaneously with the first deposition process and the second deposition process. The first deposition process and the second deposition process are performed at a temperature less than about 500 degrees Celsius and at a pressure in a range from about 10 Torr about 50 Torr. The method further includes a third deposition process performed subsequent to the second deposition process, the third deposition process forming an undoped semiconductor layer on the n-type doped capping layer. The exposed surface of the substrate comprises one or more monocrystalline surfaces and one or more non-monocrystalline surfaces, the epitaxial portion of the n-type doped semiconductor layer selectively formed on the one or more monocrystalline surfaces and the amorphous portion of the n-type doped semiconductor layer formed on the one or more non-monocrystalline surfaces.

In another aspect, a semiconductor structure is provided. The semiconductor structure includes a stack of alternating doped semiconductor epitaxial layers and cap epitaxial layers formed on a substrate. Each doped semiconductor epitaxial layer includes silicon having a first n-type dopant. Each cap epitaxial layer includes silicon having a second n-type dopant different from the first n-type dopant. The first n-type dopant includes phosphorous. The second n-type dopant includes arsenic, antimony, or both arsenic and antimony. The stack of alternating doped semiconductor epitaxial layers and cap epitaxial layers have a thickness in a range from about 10 Å to about 1,000 Å.

Implementations may include one or more of the following. The first n-type dopant includes phosphorous. The second n-type dopant includes arsenic, antimony, or both arsenic and antimony. The stack of alternating doped semiconductor epitaxial layers and cap epitaxial layers have a thickness in a range from about 10 Å to about 1,000 Å.

In yet another aspect, a processing system is provided. The system includes a processing chamber and a system controller. The system controller is configured to cause the processing system to perform a first deposition process, a second deposition process subsequent to the first deposition process, and an etch process. The first deposition process includes forming an n-type doped semiconductor layer including a first n-type dopant on an exposed surface of a substrate. The second deposition process forming an n-type doped capping layer on the n-type doped semiconductor layer, the n-type doped capping layer including a second n-type dopant different from the first n-type dopant. The etch process selectively removing an amorphous portion of the n-type doped semiconductor layer and an amorphous portion of the n-type doped capping layer, and leaving an epitaxial portion of the n-type doped semiconductor layer and optionally an epitaxial portion of the n-type doped capping layer. The n-type doped semiconductor layer and the n-type doped capping layer comprise silicon.

Implementations may include one or more of the following. The first n-type dopant includes phosphorus. The first deposition process includes flowing a silicon-containing precursor in the processing chamber. The second deposition process includes flowing the silicon-containing precursor and a second n-type dopant source in the processing chamber. The etch process includes flowing an etchant gas and a carrier gas in a processing gas, subsequent to the second deposition process. The etch process includes flowing an etchant gas and a carrier gas in a processing gas, simultaneously with the first deposition process and the second deposition process. The first deposition process and the second deposition process are performed at a temperature less than about 500 degrees Celsius and at a pressure in a range from about 10 Torr about 50 Torr. The exposed surface of the substrate comprises one or more monocrystalline surfaces and one or more non-monocrystalline surfaces, the epitaxial portion of the n-type doped semiconductor layer selectively formed on the one or more monocrystalline surfaces and the amorphous portion of the n-type doped semiconductor layer formed on the one or more non-monocrystalline surfaces.

In another aspect, a non-transitory computer readable medium has stored thereon instructions, which, when executed by a processor, causes the process to perform operations of the above apparatus and/or method.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 illustrates a schematic side view of one example of a deposition chamber in accordance with one or more implementations of the present disclosure.

FIG. 2 illustrates a cross-sectional view of a semiconductor device in accordance with one or more implementations of the present disclosure.

FIG. 3 illustrates a cross-sectional view of another semiconductor device in accordance with one or more implementations of the present disclosure.

FIG. 4 illustrates an exemplary flow chart of a method for manufacturing a semiconductor device in accordance with one or more implementations of the present disclosure.

FIGS. 5A-5E illustrate view of various stages of manufacturing a semiconductor device in accordance with one or more implementations of the present disclosure.

FIG. 6 illustrates an exemplary flow chart of another method for manufacturing a semiconductor device in accordance with one or more implementations of the present disclosure.

FIGS. 7A-7E illustrate view of various stages of manufacturing a semiconductor device in accordance with one or more implementations of the present disclosure.

To facilitate understanding, identical reference numerals have been used, where possible, to designate identical elements that are common to the figures. It is contemplated that elements and features of one implementation may be beneficially incorporated in other implementations without further recitation.

### DETAILED DESCRIPTION

The present disclosure generally relates to the field of semiconductor devices and methods for manufacturing semiconductor devices. More particularly, the disclosure relates to low temperature selective deposition of epitaxial silicon-containing films.

The three-dimensional nature of advance logic architectures, for example, complementary metal-oxide-semiconductor (CMOS) logic and memory scaling, involve growing epitaxial structures in more complex and restrictive geometries composed of an ever increasing different range of materials. In addition, changing demands on epitaxial doping levels and decreasing thermal budgets place additional burdens on traditional selective epitaxial deposition processes.

Phosphorus-doped selective epitaxial technology has gained interest as a method to reduce external transistor resistance in source/drain of n-type metal-oxide semiconductor (MOS) devices. High phosphorous doping ensures low contact resistance when metal contacts are formed. However, phosphorous dopants of high concentration tend to diffuse into adjacent layers, preventing control of doping profile in the phosphorus-doped epitaxial layer. For example, at temperatures of 550 degrees Celsius or less, n-type silicon epitaxy by thermal vapor deposition (CVD) often includes a cyclic growth followed by etch process. One example of such a process sequence includes deposition of Si:P followed by deposition of undoped silicon followed by etching in chlorine gas. The first two deposition processes grow epitaxial Si:P/Si layers on the silicon window and amorphous Si:P/Si on the surrounding dielectrics. The etching process selectively removes amorphous Si:P/Si leaving the epitaxial Si:P/Si layers. The removal rates during the etching process can be similar for both the epitaxial Si:P/Si layers formed on the silicon window and the amorphous Si:P/Si formed on the surrounding dielectrics, so the process window is narrow or even non-existent. One reason is that the phosphorus in Si:P can diffuse into Si so the Si:P/Si stack becomes phosphorous-doped. Once the Si layer is somewhat phosphorous-doped, the removal rates of epitaxial Si and amorphous Si become close or equal.

In one or more implementations, which can be combined with other implementations, the process sequence is modified from [(Si:P)+ (undoped Si)+ (etch in Cl₂ gas)] to either [(Si:P)+ (Si:As or Si:Sb)+ (undoped Si)+ (etch in Cl₂ gas)] or [(Si:P)+ (Si:As or Si:Sb)+ (etch in Cl₂ gas)]. Arsenic in Si:As or antimony in Si:Sb can block phosphorous diffusion into either (undoped Si) or (Si:As) so as to increase the removal rate ratio of epitaxial to amorphous films, and widen the process window. Both arsenic and antimony in Si not only block phosphorous diffusion but are also n-type dopants. The epitaxial layers deposited using the epitaxial deposition techniques described not only contain phosphorous but also have a high concentration of activated phosphorous and/or antimony.

The deposition method described has improved throughput compared to conventional cyclic deposition and etch processes. The process described is more compatible with various chambers in mass production. The ability to retard phosphorous diffusion into adjacent layers enables deposition of an epitaxial film with a high level of dopant, for example, an a phosphorous dopant concentration of greater than 3×10²¹ atoms per cubic centimeter, which is beneficial for resistivity tuning. The improved etch selectively of the process described widens the process window tuning, thus increasing adaptability and feasibility.

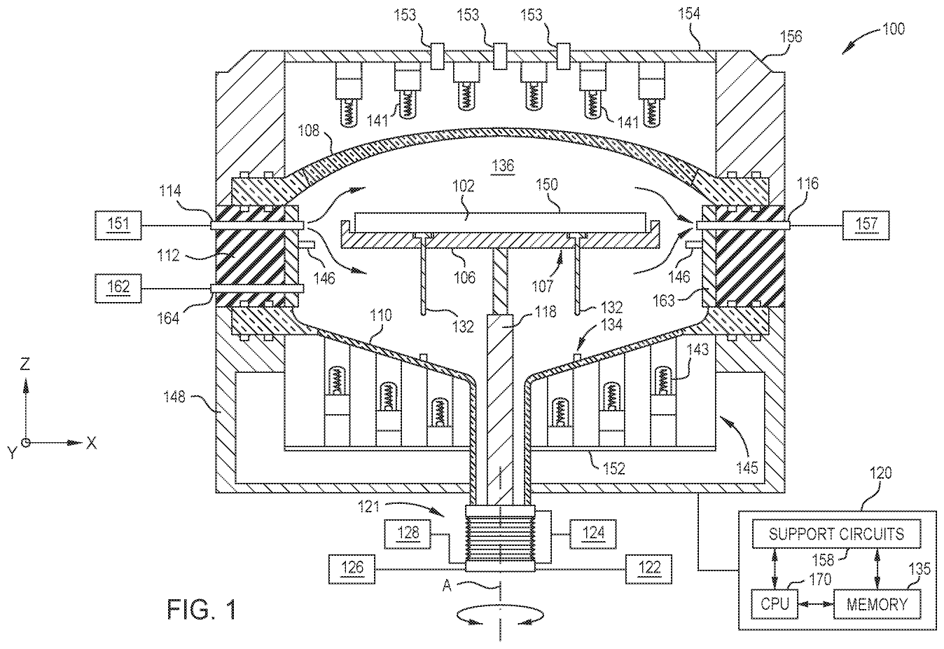

FIG. 1 is a schematic illustration of a type of deposition chamber 100 according to one implementation of the present disclosure. The deposition chamber 100 is utilized to grow an epitaxial film on a substrate, such as the substrate 102. The deposition chamber 100 may be used to perform the methods described herein, for example, the method 400 and the method 600. The deposition chamber 100 creates a cross-flow of precursors across the top surface 150 of the substrate 102.

The deposition chamber 100 includes an upper body 156, a lower body 148 disposed below the upper body 156, a flow module 112 disposed between the upper body 156 and the lower body 148. The upper body 156, the flow module 112, and the lower body 148 form a chamber body. Disposed within the chamber body is a substrate support 106, an upper dome 108, a lower dome 110, a plurality of upper lamps 141, and a plurality of lower lamps 143. The substrate support 106 is disposed between the upper dome 108 and the lower dome 110. The plurality of upper lamps 141 are disposed between the upper dome 108 and a lid 154. The lid 154 includes a plurality of sensors 153 disposed therein for measuring the temperature within the deposition chamber 100. The plurality of lower lamps 143 are disposed between the lower dome 110 and a floor 152. The plurality of lower lamps 143 form a lower lamp assembly 145.

A processing region 136 is formed between the upper dome 108 and the lower dome 110. The processing region 136 has the substrate support 106 disposed therein. The substrate support 106 includes a top surface on which the substrate 102 is disposed. The substrate support 106 is attached to a shaft 118. The shaft 118 is connected to a motion assembly 121. The motion assembly 121 includes one or more actuators and/or adjustment devices that provide movement and/or adjustment of the shaft 118 and/or the substrate support 106 within the processing region 136. The motion assembly 121 includes a rotary actuator 122 that rotates the shaft 118 and/or the substrate support 106 about a longitudinal axis A of the deposition chamber 100. The motion assembly 121 further includes a vertical actuator 124 to lift and lower the substrate support 106 in the z-direction. The motion assembly 121 includes a tilt adjustment device 126 that is used to adjust the planar orientation of the substrate support 106 and a lateral adjustment device 128 that is used to adjust the position of the shaft 118 and the substrate support 106 side to side within the processing region 136.

The substrate support 106 may include lift pin holes 107 disposed therein. The lift pin holes 107 are sized to accommodate a lift pin 132 for lifting of the substrate 102 from the substrate support 106 either before or after a deposition process is performed. The lift pins 132 may rest on lift pin stops 134 when the substrate support 106 is lowered from a processing position to a transfer position.

The flow module 112 includes a plurality of process gas inlets 114, a plurality of purge gas inlets 164, and one or more exhaust gas outlets 116. The plurality of process gas inlets 114 and the plurality of purge gas inlets 164 are disposed on the opposite side of the flow module 112 from the one or more exhaust gas outlets 116. One or more flow guides 146 are disposed below the plurality of process gas inlets 114 and the one or more exhaust gas outlets 116. The flow guide 146 is disposed above the purge gas inlets 164. A liner 163 is disposed on the inner surface of the flow module 112 and protects the flow module 112 from reactive gases used during deposition processes. The process gas inlets 114 and the purge gas inlets 164 are positioned to flow a gas parallel to the top surface 150 of a substrate 102 disposed within the processing region 136. The process gas inlets 114 are fluidly connected to a process gas source 151. The purge gas inlets 164 are fluidly connected to a purge gas source 162. The one or more exhaust gas outlets 116 are fluidly connected to an exhaust pump 157. Each of the process gas source 151 and the purge gas source 162 may be configured to supply one or more precursors or process gases into the processing region 136.

The deposition chamber 100 further includes a controller 120. The controller 120 can include a central processing unit (CPU) 170, memory 135, and support circuits (or I/O) (not shown). The CPU 170 may be one of any form of computer processors that are used in industrial settings for controlling various processing and hardware (e.g., process gas delivery, purge gas delivery, and other hardware) and monitor the processes (e.g., processing time, susceptor and/or substrate position, power to the lamp assemblies). The memory 135 is connected to the CPU 170, and may be one or more of readily available memory, such as random access memory (RAM), read only memory (ROM), floppy disk, hard disk, or any other form of digital storage, local or remote. Software instructions and data can be coded and stored within the memory 135 for instructing the CPU 170. The support circuits 158 are also connected to the CPU 170 for supporting the processor in a conventional manner. The support circuits 158 may include conventional cache, power supplies, clock circuits, input/out circuitry, subsystems, and the like. A program (or computer instructions) readable by the controller 120 determines which tasks are performable. The program may be software readable by the controller 120 and may include code to monitor and control (e.g., switch between), for example, the various gas sources (phosphorous-containing source gas, the one or more deposition gases, the n-type dopant gas). The controller 120 may be used to provide instructions to the deposition chamber 100 to perform the methods described herein, for example, the method 400 and the method 600.

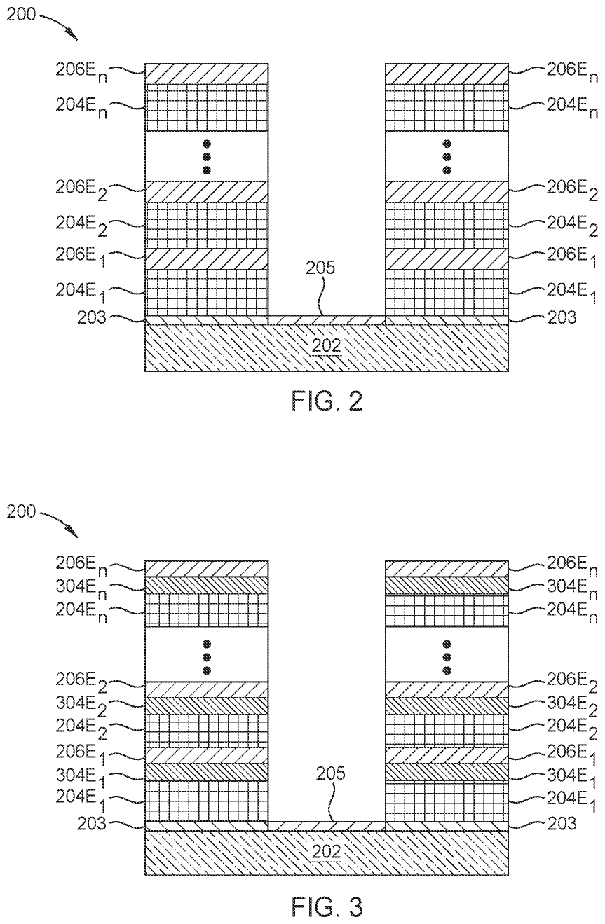

FIG. 2 illustrates a cross-sectional view of a semiconductor device 200 in accordance with one or more implementations of the present disclosure. The semiconductor device 200 includes a doped semiconductor layer and a capping layer, according to one or more implementations of the present disclosure. A doped semiconductor layer, doped with n-type carrier dopants, such as phosphorous, may be used as a source/drain in negative metal-oxide semiconductor (NMOS) devices.

In some implementations, the semiconductor device 200 is a portion of an IC chip, a system on chip (SoC), or portion thereof, that includes various passive and active microelectronic devices such as resistors, capacitors, inductors, diodes, p-type field effect transistors (PFETs), n-type field effect transistors (NFETs), FinFET, nanosheet FETs, nanowire FETs, other types of multi-gate FETs, metal-oxide semiconductor field effect transistors (MOSFETs), CMOS transistors, bipolar junction transistors (BJTs), laterally diffused MOS (LDMOS) transistors, high voltage transistors, high frequency transistors, memory devices, other suitable components, or combinations thereof. FIG. 2 has been simplified for the sake of clarity to better understand the implementations of the present disclosure. Additional features can be added in the semiconductor device 200, and some of the features described below can be replaced, modified, or eliminated in other implementations of the semiconductor device 200.

The semiconductor device 200 includes a device substrate 202, and a stack of alternating epitaxial portions 204E₁, 204E₂ . . . 204Eₙ (collectively 204E) of a doped semiconductor layer and epitaxial portions 206E₁, 206E₂ . . . 206Eₙ (collectively 206E) of a cap layer interposed between the epitaxial portions 204E of the doped semiconductor layers, formed on the device substrate 202.

The semiconductor device 200 includes a device substrate 202 as depicted in FIG. 2. The term “substrate” as used herein refers to a layer of material that serves as a basis for subsequent processing operations. It is contemplated that the device substrate 202 may be a planar substrate or a patterned substrate. The device substrate 202 can include multiple layers. Patterned substrates are substrates that include electronic features formed into or onto a processing surface of the substrate. The device substrate 202 may contain monocrystalline surfaces 203 and/or one or more secondary surfaces 205 that are non-monocrystalline, such as polycrystalline or amorphous surfaces. The secondary surface 205 may be, for example, a patterned dielectric. Monocrystalline surfaces include the bare crystalline substrate or a deposited single crystal layer usually made from a material such as silicon, germanium, silicon germanium or silicon carbon. Polycrystalline or amorphous surfaces may include dielectric materials, such as oxides or nitrides, specifically silicon oxide or silicon nitride, as well as amorphous silicon surfaces. It is understood that the device substrate 202 may include multiple layers, or include, for example, partially fabricated devices such as transistors, flash memory devices, and the like.

The device substrate 202 may further include integrated circuit devices (not shown). For example, the device substrate 202 may further include FinFET transistors in addition to interconnect structures. As one of ordinary skill in the art will recognize, a wide variety of integrated circuit devices such as transistors, diodes, capacitors, resistors, the like, or combinations thereof may be formed in and/or on the device substrate 202 to generate the structural and functional requirements of the design for the resulting semiconductor device 200.

The epitaxial portions 204E of the doped semiconductor epitaxial layers are formed of silicon (Si) or silicon germanium (SiGe) with a ratio of germanium (Ge) ranging between 1% and 100%, for example, a ratio of Ge ranging between 1% and 10%. The epitaxial portions 204E of the doped semiconductor epitaxial layers may be doped with n-type carrier dopants such as phosphorus (P) or antimony (Sb) with the concentration between about 10¹⁹ cm⁻³ and 5·×10²¹ cm⁻³, depending upon the targeted conductive characteristic of the semiconductor device 200. The epitaxial portions 204E of the doped semiconductor epitaxial layers may be doped with p-type carrier dopants such as boron (B), gallium (Ga), aluminum (Al), or indium (In) with the concentration of between about 1020 cm⁻³ and 5×10²¹ cm⁻³, depending upon the targeted conductive characteristic of the semiconductor device 200. In one or more implementations, which can be combined with other implementations, the epitaxial portions 204E of the doped semiconductor epitaxial layers are Si:P epitaxial layers.

The epitaxial portions 206E of the cap layers are formed of silicon (Si) or silicon germanium (SiGe) with a ratio of germanium (Ge) ranging between 1% and 100%, for example, a ratio of Ge ranging between 1% and 10%. The epitaxial portions 206E of the cap layers can reduce or prevent migration of the n-type dopant from the underlying epitaxial portions 204E of the doped semiconductor epitaxial layers into the epitaxial portions 206E of the cap layers 206, which is believed to block migration of the phosphorous dopant into adjacent layers thus improving the etch selectivity of the epitaxial layers relative to any amorphous or polycrystalline materials present on the device substrate 202. The epitaxial portions 204E of the doped semiconductor epitaxial layers may be doped with n-type carrier dopants such as antimony (Sb) or arsenic (As) with the concentration between about 10¹⁹ cm⁻³ and 5·×10²¹ cm⁻³, depending upon the targeted conductive characteristic of the semiconductor device 200. The epitaxial portions 206E of the cap layers include an n-type carrier dopant, which is different from the n-type carrier dopant present in the epitaxial portions 204E of the doped semiconductor layer. For example, if the epitaxial portions 204E of the doped semiconductor epitaxial layers are Si:P epitaxial layers, the epitaxial portion 206E of the cap layers can be Si:Sb epitaxial layers or Si:As epitaxial layers. Not to be bound by theory but it is believed that the phosphorous in Si:P can diffuse into silicon so the Si:P/Si stack becomes phosphorous doped. Once the silicon layer becomes somewhat phosphorous doped, the removal rates of the epitaxial silicon layers and any amorphous silicon layers present become close or equal. However the arsenic in Si:As and the antimony and Si:Sb present in the capping layer can block phosphorous diffusion so as to increase the removal rate ratio of epitaxial silicon relative to amorphous silicon, thus widening the process window.

The epitaxial portions 204E of the doped semiconductor layers 204 may each have a thickness in a range from about 15 Å to about 20 Å. The epitaxial portions 206E of the cap layers 206 may each have a thickness in a range from about 5 Å to about 15 Å. The semiconductor device 200 may have about 30 pairs of the epitaxial portions 204E of the doped semiconductor layers and the epitaxial portions 206E of the cap layers 206, having a total thickness in a range from about 10 Å to about 1,000 Å, or in a range from about 100 Å to about 700 Å, for example, about 600 Å.

FIG. 3 illustrates a cross-sectional view of a semiconductor device 300 in accordance with one or more implementations of the present disclosure. Similar to the semiconductor device 200, the semiconductor device 300 includes a doped semiconductor epitaxial layer, for example, the epitaxial portions 204E of the doped semiconductor layers and a capping layer, for example, the epitaxial portions 206E of the cap layers. The semiconductor device 300 further includes epitaxial portions 304E₁, 304E₂ . . . 304Eₙ (collectively 304E) of an undoped semiconductor layer. As depicted in FIG. 3, the epitaxial portions 304E of the undoped semiconductor layers, can be formed in between the epitaxial portions 204E of the doped semiconductor layers 204 and the epitaxial portions 206E of the cap layers 206 such that the epitaxial portion 304E of the undoped semiconductor layer is formed on the epitaxial portion 204E of the doped semiconductor layer and the epitaxial portion 206E of the cap layers is formed on the epitaxial portion 204E of the undoped semiconductor layer. It should be noted that epitaxial portions 304E of the undoped semiconductor epitaxial layer can be formed in other locations within the semiconductor device 300. For example, a first epitaxial portion of a first undoped semiconductor layer can be formed under the epitaxial portion 206E of the cap layer as is shown in FIG. 3 and another epitaxial portion of a second undoped semiconductor layer may be formed on the surface of the epitaxial portions 206E of the cap layer, for example, in between the epitaxial portion 206E₁ of a first doped semiconductor layer and the epitaxial portion 204E₂ of a second doped semiconductor layer.

The epitaxial portions 304E of the undoped semiconductor epitaxial layers are formed of silicon (Si) or silicon germanium (SiGe) with a ratio of germanium (Ge) ranging between 1% and 100%, for example, a ratio of Ge ranging between 1% and 10%. The epitaxial portions 304E of the undoped semiconductor epitaxial layers may each have a thickness of between about 5 Å and about 15 Å.

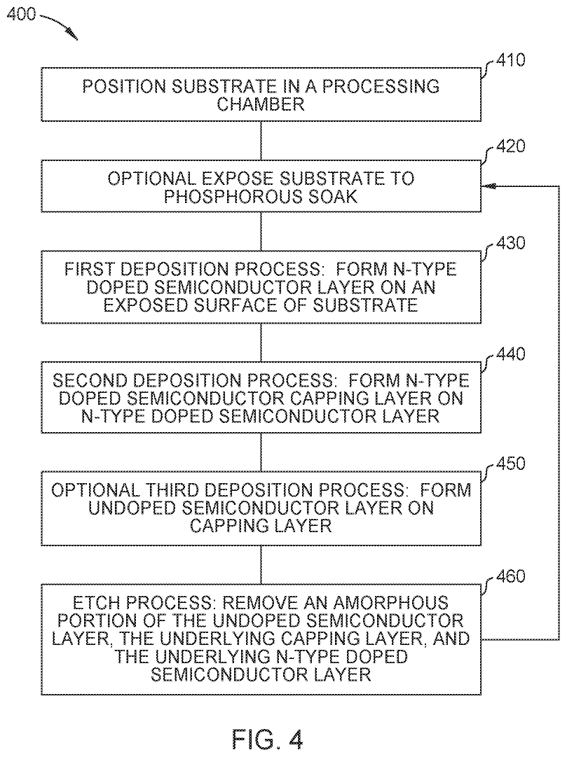

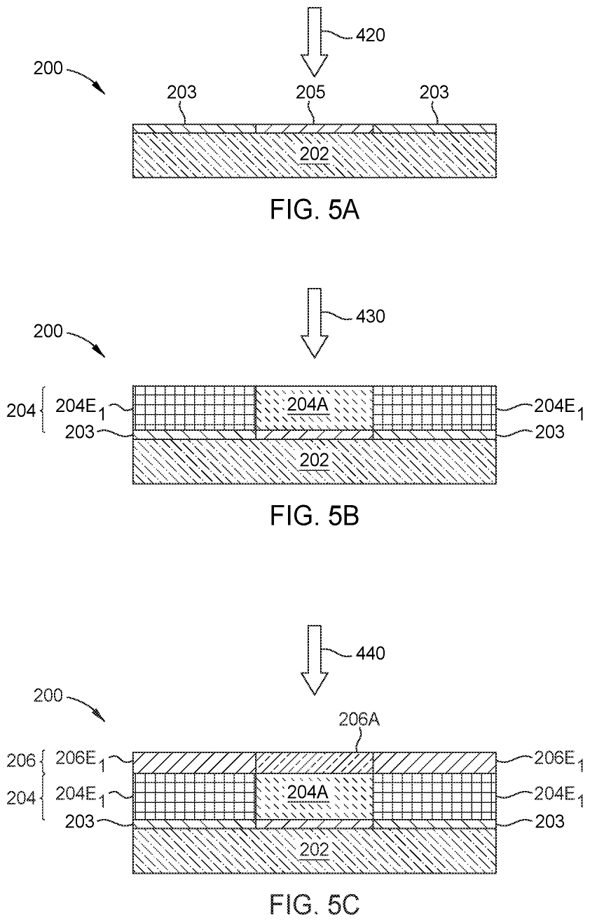

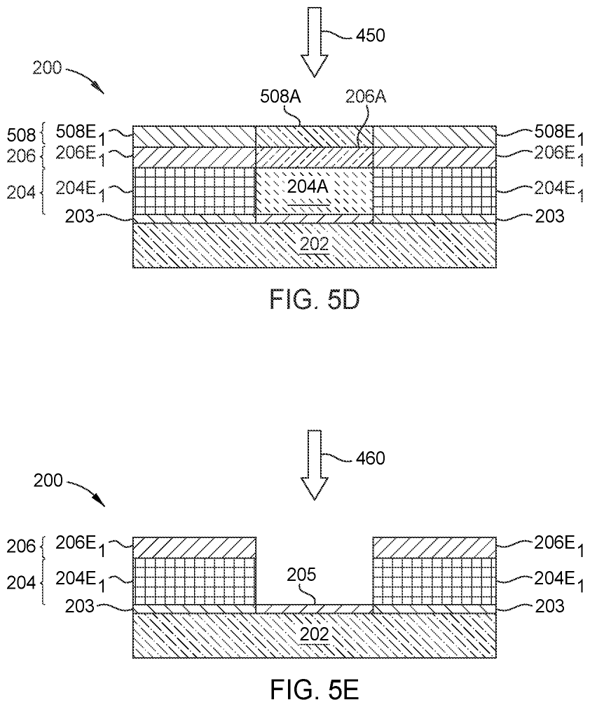

FIG. 4 illustrates a flow chart of a method 400 for manufacturing a semiconductor device in accordance with one or more implementations of the present disclosure. The semiconductor device may be the semiconductor device 200 shown in FIG. 2. FIGS. 5A-5E illustrate views of various stages of manufacturing a semiconductor device in accordance with one or more implementations of the present disclosure. Although FIGS. 5A-5E are described in relation to the method 400, it will be appreciated that the structures disclosed in FIGS. 5A-5E are not limited to the method 400, but instead may stand alone as structures independent of the method 400. Similarly, although the method 400 is described in relation to FIGS. 5A-5E, it will be appreciated that the method 400 is not limited to the structures disclosed in FIGS. 5A-5E but instead may stand alone independent of the structures disclosed in FIGS. 5A-5E. It should be understood that FIGS. 5A-5E illustrate only partial schematic views of the semiconductor device 200, and the semiconductor device 200 may contain any number of transistor sections and additional materials having aspects not illustrated in the figures. It should also be noted that although the method 400 illustrated in FIG. 4 is described sequentially, other process sequences that include one or more operations that have been omitted and/or added, and/or has been rearranged in another desirable order, fall within the scope of the implementations of the disclosure provided herein.

Referring to FIG. 5A, at operation 410, a semiconductor device substrate, for example, the device substrate 202 is positioned within a processing chamber. The processing chamber may be an epitaxial deposition chamber, for example, the deposition chamber 100 depicted in FIG. 1. The device substrate 202 is heated to a target temperature. The target temperature is below the thermal budget of the semiconductor device 200, for example, a temperature of 550 degrees Celsius or less or a temperature of 500 degrees Celsius or less or a temperature of 450 degrees Celsius or less. In at least one implementations, the temperature in the processing chamber may be adjusted so that a reaction region formed at or near an exposed surface of the semiconductor device 300, or that the surface of the semiconductor device 200, is about 550 degrees Celsius or less, or about 500 degrees Celsius or less, or about 480 degrees Celsius or less, or about 400 degrees Celsius or less, or about 350 degrees Celsius or less. In one example, the substrate is heated to a temperature in a range from about 350 degrees Celsius to about 500 degrees Celsius, or in a range from about 350 degrees Celsius to about 480 degrees Celsius, or in a range from about 350 degrees Celsius to about 400 degrees Celsius, or in a range from about 400 degrees Celsius to about 480 degrees Celsius.

Referring to FIG. 5A, optionally at operation 420 the device substrate 202 is exposed to a phosphorous soak process, for example, a phosphine soak process. The phosphorous soak process is performed by flowing a phosphorous-containing source gas into the processing region. Not to be bound by theory but it is believed that the phosphorous soak process incorporates an appropriate amount of phosphorous dopant to reduce film resistivity, which may lead to improved mobility or improved activation. In some implementations, the substrate surface is exposed to a phosphorous soak process at the temperature established during operation 410, for example, a temperature of 500 degrees Celsius or less. The phosphorous soak process may be performed at a first pressure within a range from about 5 Torr to about 100 Torr, or in a range from about 5 Torr to about 80 Torr, or in a range from about 10 Torr to about 50 Torr, or in a range from about 10 Torr to about 40 Torr, or in a range from about 5 Torr to about 40 Torr. The soak may be conducted to the substrate surface for a period of time in the range from about 1 second to about 90 seconds. In one implementation, the soak will last for about 70 seconds or less. In another implementation, the soak will last for about 50 seconds or less. In another implementation, the soak will last for about 20 seconds. In yet another implementation, the soak will last for about 10 seconds or less. However, the period of time for the soak process may be adjusted based on the pressure at which the soak process is performed. The flow rate of phosphine gas can be in the range from about 10 sccm to about 2,000 sccm, preferably from about 50 sccm to about 500 sccm.

In at least one implementation, the phosphorous-containing source gas includes one or a combination of phosphine source gas, phosphorous halide source gases, and organic phosphorous source gases, for example, alkylphosphines. Phosphorous halide source gases may include compounds with the formula PH(3-x)X′x where H is hydrogen, X′ is a halogen such as Cl, F, Br, or I, and x=1, 2, or 3. Suitable examples of phosphorous halide source gases include PCl₃. Organic phosphorous source gases may include alkylphosphine compounds with the formula RxPH(3-x), where R is methyl, ethyl, propyl, or butyl, H is hydrogen, and x=1, 2, or 3. Suitable alkylphosphines include trimethylphosphine ((CH₃)₃P), dimethylphosphine ((CH₃)₂PH), triethylphosphine ((CH₃CH₂)₃P), tert-butylphosphine, and diethylphosphine ((CH₃CH₂)₂PH). In at least one particular implementation, phosphine is used.

The phosphorous-containing source gas may be provided along with a carrier gas. The carrier gas may have a flow rate in a range from about 1 SLM to about 100 SLM, or in a range from about 2 SLM to about 30 SLM, or in a range from about 2 SLM to about 5 SLM. Suitable carrier gases include nitrogen (N2), hydrogen (H2), argon, helium, or combinations thereof. The carrier gas may be selected based on the reactants used and/or the process temperature during the soak process. In one or more implementations, which can be combined with other implementations, phosphine gas is used in hydrogen carrier gas. In one example, 1-10% of phosphine gas in a hydrogen carrier is used.

Referring to FIG. 5B, at operation 430 the device substrate 202 is exposed to a first deposition process. The first deposition process forms a doped semiconductor layer 204 on one or more exposed surfaces of the device substrate 202. The first deposition process may include any suitable deposition technique, such as epitaxial (Epi) deposition, chemical vapor deposition (CVD), atomic layer deposition (ALD), or physical vapor deposition (PVD), by flowing a deposition gas in a processing chamber, such as the deposition chamber 100 shown in FIG. 1. In one or more implementations, which can be combined with other implementations, the first deposition process is an epitaxial deposition process.

The doped semiconductor layer 204 is formed of silicon (Si) or silicon germanium (SiGe) with a ratio of germanium (Ge) ranging between 1% and 100%, for example, a ratio of Ge ranging between 1% and 10%. The doped semiconductor layer 204 may be doped with n-type carrier dopants such as phosphorus (P) or antimony (Sb) with the concentration in a range from about 10¹⁹ cm⁻³ to about 5·×10²¹ cm⁻³, depending upon the targeted conductive characteristic of the semiconductor device 200. The doped semiconductor layer 204 may be doped with p-type carrier dopants such as boron (B), gallium (Ga), aluminum (Al), or indium (In) with the concentration of between about 1020 cm⁻³ and 5×10²¹ cm⁻³, depending upon the targeted conductive characteristic of the semiconductor device 200.

In some implementations, the deposition gas used in the first deposition process includes a silicon-containing precursor, a germanium-containing precursor, a dopant source, or a combination thereof. The silicon-containing precursor may include silane (SiH₄), disilane (Si₂H₆), trisilane (Si₃H₈), tetrasilane (Si₄H₁₀), or a combination thereof. The germanium-containing precursor may include germane (GeH₄), germanium tetrachloride (GeCl₄), and digermane (Ge₂H₆). The dopant source may include a phosphorous-containing precursor, an antimony-containing precursor, and arsenic-containing precursor, or a combination thereof. The phosphorous-containing precursor may be as described herein. The antimony-containing precursor can be one or a combination of stibine, antimony trichloride, antimony tetrachloride, antimony pentachloride, triphenylantimony, antimony trihydride, antimonytrioxide, antimony pentoxide, antimony trifluoride, antimony tribromide, antimonytriiodide, antimony pentafluoride, triethyl antimony, and trimethyl antimony. The arsenic-containing precursor can include one or a combination of arsine (AsH₃), halogenated arsenic compounds, trimethylarsenic, and silylarsines [(H₃Si)₃₋ₓAsRₓ] where x=0, 1, 2, and Rx is hydrogen or deuterium. The n-type dopant source may include phosphine (PH₃), phosphorus trichloride (PCl₃), triisobutylphosphine ([(CH₃)₃C]₃P), antimony trichloride (SbCl₃), Sb(C₂H₅)₅, arsine (AsH₃), arsenic trichloride (AsCl₃), or tertiarybutylarsine (AsC₄H₁₁). The p-type dopant source may include diborane (B₂H₆), or boron trichloride (BCl₃).

In one or more implementations, which can be combined with other implementations, the deposition gas includes only the silicon-containing precursor, the germanium-containing precursor, or a combination thereof. Thus, the deposition gas does not include a dopant source instead relying on phosphorous supplied during the phosphorous soak of operation 420 to provide an n-type dopant source for doped semiconductor layer 204. In one or more other implementations, the n-type dopant can be supplied by both the phosphorous soak of operation 420 and as an n-type dopant source provided with the deposition gas.

In the first deposition process of operation 430, the doped semiconductor layer 204, as deposited, may include an epitaxial portion 204E and an amorphous portion 204A, due to, for example, different nucleation rates of the doped semiconductor layer 204 on a surface of a semiconductor region, for example, the silicon (Si) or silicon germanium (SiGe) regions, of the device substrate 202 and on a surface of a dielectric region, for example, silicon dioxide (SiO₂) or silicon nitride (Si₃N₄), of the device substrate 202. The nucleation may occur at a faster rate on the surface of the semiconductor region than on the surface of the dielectric region, and thus an epitaxial portion 204E of the doped semiconductor layer 204 may be formed selectively on the surface of the semiconductor region while an amorphous portion 204A of the doped semiconductor layer 204 may be formed on the surface of the dielectric region. The amorphous portion 204A of the doped semiconductor layer 204 may be removed in the subsequent etch process performed during operation 430.

The first deposition of operation 430 may be performed at a low temperature less than about 550 degrees Celsius or less than about 500 degrees Celsius and at a pressure in a range from about 5 Torr to about 600 Torr or in a range from about 10 Torr to about 50 Torr. The temperature of operation 430 may be the temperature established during at least one of operation 410 or operation 420. In one or more implementations, the pressure of operation 430 may be the pressure established during at least one of operation 410 or operation 420. In one or more other implementations, pressure in the processing region is increased from the first pressure of the phosphorous soak process to a second pressure suitable for growth of the doped semiconductor layer 204 at operation 430. The second pressure can be greater than the first pressure. For example, the second pressure can be 150 Torr or greater, for example, in a range from about 150 Torr to about 300 Torr.

Referring to FIG. 5C, subsequent to the first deposition process, at operation 440, a second deposition process is performed to form a cap layer 206 on the doped semiconductor layer 204. The cap layer 206 may be doped with n-type carrier dopants such as antimony (Sb) or arsenic (As) with a dopant concentration. Any suitable dopant concentration may be used. The dopant concentration may be selected based upon any of the targeted conductive characteristics of the formed semiconductor device 200, performance of the cap layer 206 in terms of etch selectivity, and performance of the cap layer 206 as a diffusion barrier. In one or more implementations, which can be combined with other implementations, the cap layer 206 may be doped with n-type carrier dopants such as antimony (Sb) or arsenic (As) with a concentration between about 10¹⁹ cm⁻³ and 5·×10²¹ cm⁻³. The cap layer 206 include an n-type carrier dopant, which is different from the n-type carrier dopant present in the doped semiconductor layer 204. For example, if the doped semiconductor layers 204 are Si:P layers, the cap layers 206 can be Si:Sb layers or Si:As epitaxial layers.

The second deposition process may include any suitable deposition technique, such as epitaxial (Epi) deposition, chemical vapor deposition (CVD), atomic layer deposition (ALD), or physical vapor deposition (PVD), by flowing a deposition gas in a processing chamber, such as the deposition chamber 100 shown in FIG. 1. In one or more implementations, which can be combined with other implementations, the second deposition process is an epitaxial deposition process.

In some implementations, the second deposition gas used in the second deposition process includes a silicon-containing precursor, a germanium-containing precursor, a dopant source, or a combination thereof. The silicon-containing precursor may include silane (SiH₄), disilane (Si₂H₆), trisilane (Si₃H₈), tetrasilane (Si₄H₁₀), or a combination thereof. The germanium-containing precursor may include germane (GeH₄), germanium tetrachloride (GeCl₄), and digermane (Ge₂H₆). The n-type dopant source may be as described for the first deposition gas. The n-type dopant source may include antimony trichloride (SbCl₃), trimethylstibine (Sb(CH₃)₃), triethylstibine (Sb(C₂H₅)₃), arsine (AsH₃), triethylarsine (As(C₂H₅)₃), triethyl arsenate (AsO₄C₆H₁₅), arsenic trichloride (AsCl₃), or tertiarybutylarsine (AsC₄H₁₁). The n-type dopant source of the second deposition process is different from the n-type dopant source of the first deposition process. In one or more implementations, the second deposition gas used in the second deposition process includes the same silicon-containing precursor and/or the same germanium-containing precursor used in the first deposition process. In one or more other implementations, the second deposition gas used in the second deposition process includes a different silicon-containing precursor and/or different germanium-containing precursor relative to the precursors used in the first deposition process.

In the second deposition process of operation 430, the cap layer 206 may include an epitaxial portion 206E and an amorphous portion 206A due to different nucleation rates of the cap layer 206 on a surface of the epitaxial portion 204E of the doped semiconductor layer 204 and a surface of the amorphous portion 204A of the doped semiconductor layer 204. The nucleation may occur at a faster rate on the surface of the epitaxial portion 204E of the doped semiconductor layer 204 than on the surface of the amorphous portion 204A of the doped semiconductor layer 204, and thus an epitaxial portion 206E of the cap layer 206 may be formed selectively on the surface of the epitaxial portion 204E of the doped semiconductor layer 204 while an amorphous portion 206A of the cap layer 206 may be formed on the surface of the amorphous portion 204A of the doped semiconductor layer 204. The amorphous portion 206A of the cap layer 206 may be removed in the subsequent etch process performed during operation 460. The epitaxial portion 206E of the cap layer 206 may be completely or partially removed in the subsequent etch process performed during operation 460.

The second deposition process of operation 440 may be performed at a low temperature less than about 550 degrees Celsius or less than about 500 degrees Celsius and at a pressure of between 5 Torr and 600 Torr or in a range from about 10 Torr to about 50 Torr. In one or more implementations, the second deposition process is performed at a temperature and pressure similar to or the same as the temperature and pressure of the first deposition process. In one or more other implementations, the second deposition process is performed at a temperature and pressure different from the temperature and pressure of the first deposition process.

Referring to 5D, optionally at operation 450, subsequent to a second deposition process, a third deposition process may be performed for form an undoped semiconductor layer 508 on the cap layer 206. The third deposition process may include any suitable deposition technique, such as epitaxial (Epi) deposition, chemical vapor deposition (CVD), atomic layer deposition (ALD), or physical vapor deposition (PVD), by flowing a deposition gas in a processing chamber, such as the deposition chamber 100 shown in FIG. 1. In one or more implementations, which can be combined with other implementations, the third deposition process is an epitaxial deposition process.

The undoped semiconductor layer 508 is formed of silicon (Si) or silicon germanium (SiGe) with a ratio of germanium (Ge) ranging between 1% and 100%, for example, a ratio of Ge ranging between 1% and 10%.

In some implementations, the third deposition gas used in the third deposition process includes a silicon-containing precursor, a germanium-containing precursor, a dopant source, or a combination thereof. The silicon-containing precursor may include silane (SiH₄), disilane (Si₂H₆), trisilane (Si₃H₈), tetrasilane (Si₄H₁₀), or a combination thereof. The germanium-containing precursor may include germane (GeH₄), germanium tetrachloride (GeCl₄), and digermane (Ge₂H₆). The third deposition gas used in the third deposition process may further include a carrier gas.

In one or more implementations, the third deposition gas used in the third deposition process includes the same silicon-containing precursor and/or the same germanium-containing precursor as the second deposition gas used in the second deposition process. In one or more other implementations, the third deposition gas used in the third deposition process includes a different silicon-containing precursor and/or different germanium-containing precursor relative to the precursors used in the second deposition process.

In one or more implementations, which can be combined with other implementations the third deposition gas includes only the silicon-containing precursor, the germanium-containing precursor, or a combination thereof. Thus, the third deposition gas does not include a dopant source.

In one or more implementations, which can be combined with other implementations the undoped semiconductor layer 508 is formed by continuing the flow of the silicon-containing precursor from the second deposition gas while ceasing the flow of the antimony or arsenic dopant used in the second deposition gas.

In the third deposition process of operation 450, the undoped semiconductor layer 508, as deposited, may include an epitaxial portion 508E₁ and an amorphous portion 508A, due to, for example, different nucleation rates of the undoped semiconductor layer 508 on a surface of the underlying epitaxial portion 206E and a surface of the underlying amorphous portion 206A of the cap layer 206. The nucleation may occur at a faster rate on the surface of the epitaxial portion 206E of the cap layer 206 than on the surface of the amorphous portion 206A of the cap layer 206, and thus an epitaxial portion 508E₁ of the undoped semiconductor layer 508 may be formed selectively on the surface of the epitaxial portion 206E of the cap layer 206 while an amorphous portion 508A of the undoped semiconductor layer 508 may be formed on the surface of the amorphous portion 508A of the undoped semiconductor layer 508. The amorphous portion 508A of the undoped semiconductor layer 508 may be removed in the subsequent etch process performed during operation 460.

Referring to FIG. 5E, at operation 460, an etch process is performed to remove the amorphous portion 508A of the undoped semiconductor layer 508 (if present), the amorphous portion 206A of the cap layer 206 and the underlying amorphous portion 204A of the doped semiconductor layer 204. The etch process in operation 460 may be performed, by flowing an etching gas in the processing chamber, subsequent to the second deposition process of operation 440 or the third deposition process of operation 450 (if performed), or simultaneously with the first deposition process of operation 430, the second deposition process of operation 440, and/or the third deposition process of operation 450.

In the etch process of operation 460, the amorphous portion 206A of the cap layer 206 can be etched at a faster rate than the epitaxial portion 206E of the cap layer 206, by an appropriate etching gas, and the epitaxial portion 206E of the cap layer 206 is mostly left un-etched, as shown in FIG. 5E. Etch selectivity between the amorphous portion 206A and the epitaxial portion 206E of the cap layer 206 is greater than the etch selectivity between the epitaxial portion 204E₁ and the amorphous portion 204A of the doped semiconductor layer 204. The underlying amorphous portion 204A of the doped semiconductor layer 204 can be further etched by using the epitaxial portion 206E of the cap layer 206 as a mask, and the epitaxial portion 204E of the doped semiconductor layer 204 is left un-etched, as shown in FIG. 5E. Thus, an overall result of the epitaxial deposition process and the etch process combined can be growth of the epitaxial portion 204E of the doped semiconductor layer 204 (also referred to as the “doped semiconductor epitaxial layer”) and the epitaxial portion 206E of the cap layer 206 (also referred to as the “cap epitaxial layer”) on the substrate 202.

In some implementations, both the amorphous portion 206A and the epitaxial portion 206E of the cap layer 206 are removed during the etching process of operation 670. In other implementations, at least a portion of the epitaxial portion 206E of the cap layer 206 remains while the amorphous portion 206A is completely removed.

In some implementations where the undoped semiconductor layer 508 is present, the amorphous portion 508A of the undoped semiconductor layer 508 is etched at a faster rate than the epitaxial portion 508E₁ of the undoped semiconductor layer 508. In some implementations, both the amorphous portion 508A and the epitaxial portion 508E₁ of the undoped semiconductor layer 508 removed during the etching process of operation 460 as is shown in FIG. 5E. In other implementations, at least a portion of the epitaxial portion 508E₁ of the undoped semiconductor layer 508 remains while the amorphous portion 508A is completely removed.

The etching gas used in the etch process of operation 460 includes an etchant gas and may further include a carrier gas. The etchant gas may include halogen-containing gas, such as hydrogen chloride (HCl), chlorine (Cl₂), or hydrogen fluoride (HF). The carrier gas may include nitrogen (N₂), argon (Ar), helium (He), or hydrogen (H₂). In one or more implementations, which can be combined with other implementations, the etching gas include chlorine and a nitrogen carrier gas.

A cycle of the phosphorous soak of operation 420, the first deposition process of operation 430, the second deposition process of operation 440, optionally the third deposition process of operation 450, and the etch process of operation may be repeated as a plurality of cycles, as needed to obtain a targeted combined thickness of the epitaxial portions 204E of the doped semiconductor layer 204 and the epitaxial portions 206E of the cap layer 206 in a range from about 10 Å to about 1,000 Å, or in a range from about 100 Å to about 700 Å, for example, about 600 Å. The cycle may be repeated, for example, about 30 times.

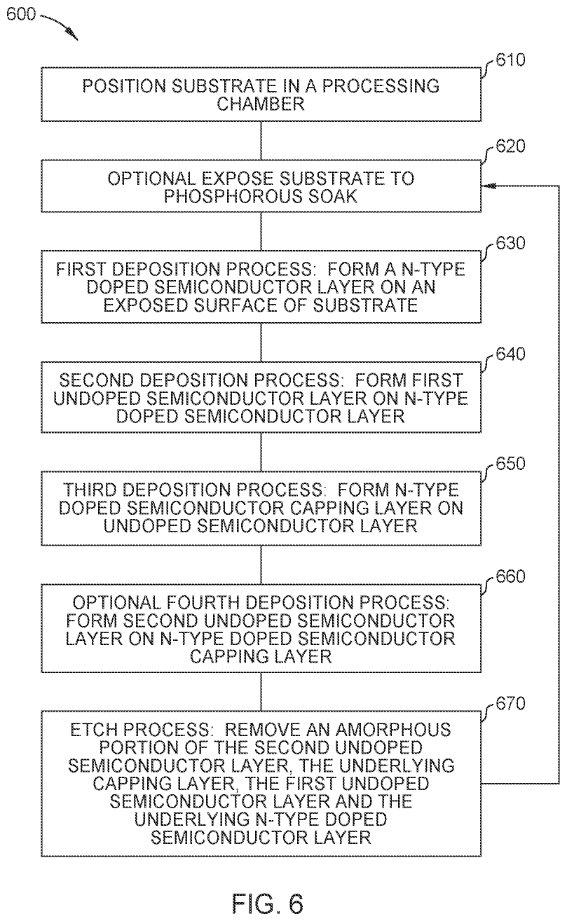

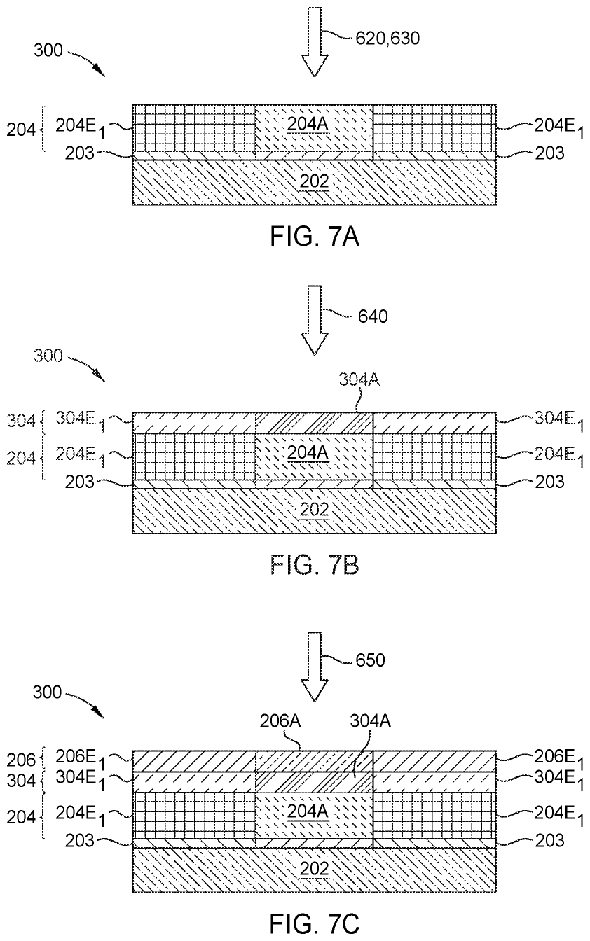

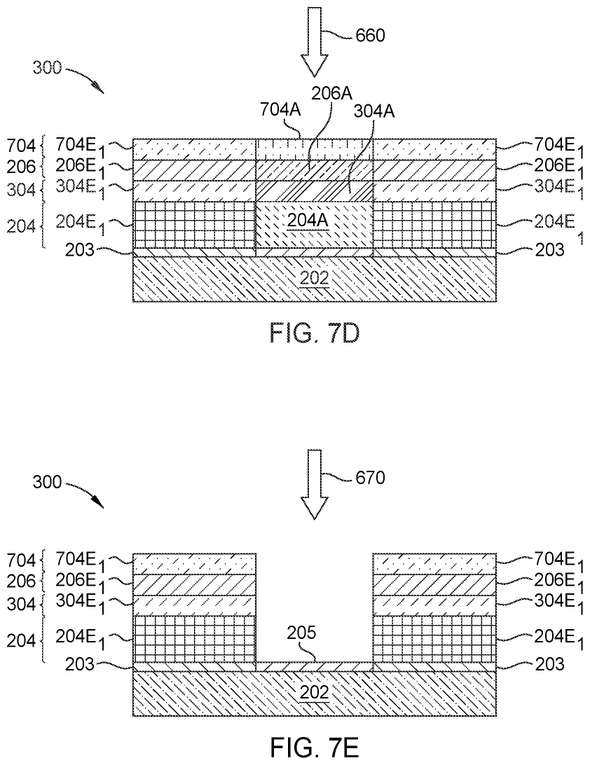

FIG. 6 illustrates a flow chart of a method 600 for manufacturing another semiconductor device in accordance with one or more implementations of the present disclosure. The semiconductor device may be the semiconductor device 300 shown in FIG. 3. FIGS. 7A-7E illustrate views of various stages of manufacturing a semiconductor device in accordance with one or more implementations of the present disclosure. Although FIGS. 7A-7E are described in relation to the method 600, it will be appreciated that the structures disclosed in FIGS. 7A-7E are not limited to the method 600, but instead may stand alone as structures independent of the method 600. Similarly, although the method 600 is described in relation to FIGS. 7A-7E, it will be appreciated that the method 600 is not limited to the structures disclosed in FIGS. 7A-7E but instead may stand alone independent of the structures disclosed in FIGS. 7A-7E. It should be understood that FIGS. 7A-7E illustrate only partial schematic views of the semiconductor device 300, and the semiconductor device 300 may contain any number of transistor sections and additional materials having aspects not illustrated in the figures. It should also be noted that although the method 600 illustrated in FIG. 6 is described sequentially, other process sequences that include one or more operations that have been omitted and/or added, and/or has been rearranged in another desirable order, fall within the scope of the implementations of the disclosure provided herein.

Referring to FIG. 7A, the method 600 begins by performing operation 610, optionally a phosphorous soak of operation 620, and a first deposition process of operation 630. Operation 610, operation 620, and operation 630 may be performed similarly to operation 410, operation 420, and operation 430 as described herein.

Referring to FIG. 7B, at operation 640, subsequent to the first deposition process, a second deposition process may be performed to form a first undoped semiconductor layer 304 on the doped semiconductor layer 204. The second deposition process may include any suitable deposition technique, such as epitaxial (Epi) deposition, chemical vapor deposition (CVD), atomic layer deposition (ALD), or physical vapor deposition (PVD), by flowing a deposition gas in a processing chamber, such as the deposition chamber 100 shown in FIG. 1. In one or more implementations, which can be combined with other implementations, the second deposition process is an epitaxial deposition process.

The first undoped semiconductor layer 304 is formed of silicon (Si) or silicon germanium (SiGe) with a ratio of germanium (Ge) ranging between 1% and 100%, for example, a ratio of Ge ranging between 1% and 10%.

In some implementations, the second deposition gas used in the second deposition process includes a silicon-containing precursor, a germanium-containing precursor, a dopant source, or a combination thereof. The silicon-containing precursor may include silane (SiH₄), disilane (Si₂H₆), trisilane (Si₃H₈), tetrasilane (Si₄H₁₀), or a combination thereof. The germanium-containing precursor may include germane (GeH₄), germanium tetrachloride (GeCl₄), and digermane (Ge₂H₆). The second deposition gas used in the second deposition process may further include a carrier gas.

In one or more implementations, which can be combined with other implementations, the second deposition gas used in the second deposition process includes only the silicon-containing precursor, the germanium-containing precursor, or a combination thereof. Thus, the deposition gas does not include a dopant source.

In one or more implementations, which can be combined with other implementations the first undoped semiconductor layer 304 is formed by continuing the flow of the silicon-containing precursor from the first deposition gas while ceasing the flow of the phosphorous dopant (if present) used in the first deposition gas.

In the second deposition process of operation 640, the first undoped semiconductor layer 304, as deposited, may include an epitaxial portion 304E and an amorphous portion 304A, due to, for example, different nucleation rates of the first undoped semiconductor layer 304 on a surface of the underlying epitaxial portion 204E₁ and a surface of the amorphous portion 204A of the doped semiconductor layer 204. The nucleation may occur at a faster rate on the surface of the epitaxial portion 204E of the doped semiconductor layer 204 than on the surface of the amorphous portion 204A of the doped semiconductor layer 204, and thus an epitaxial portion 304E of the first undoped semiconductor layer 304 may be formed selectively on the surface of the epitaxial portion 204E of the doped semiconductor layer 204 while an amorphous portion 304A of the first undoped semiconductor layer 304 may be formed on the surface of the amorphous portion 204A of the doped semiconductor layer 204. The amorphous portion 304A of the first undoped semiconductor layer 304 may be removed in the subsequent etch process performed during operation 670.

Referring to FIG. 7C, at operation 650, subsequent to the second deposition process, at operation 640, a third deposition process is performed to form a cap layer 206 on the first undoped semiconductor layer 304. The cap layer 206 may be doped with n-type carrier dopants such as antimony (Sb) or arsenic (As) with the concentration between about 10¹⁹ cm⁻³ and 5·×10²¹ cm⁻³, depending upon the targeted conductive characteristic of the semiconductor device 300. The cap layer 206 includes an n-type carrier dopant, which is different from the n-type carrier dopant present in the doped semiconductor layer 204. For example, if the doped semiconductor layer 204 is a Si:P layer, the cap layer 206 can be a Si:Sb layer or a Si:As epitaxial layers. The third deposition process of operation 650 may be performed similarly to the second deposition process of operation 440.

In some implementations, the third deposition gas used in the third deposition process includes a silicon-containing precursor, a germanium-containing precursor, a dopant source, or a combination thereof. The silicon-containing precursor may include silane (SiH₄), disilane (Si₂H₆), trisilane (Si₃H₈), tetrasilane (Si₄H₁₀), or a combination thereof. The germanium-containing precursor may include germane (GeH₄), germanium tetrachloride (GeCl₄), and digermane (Ge₂H₆). The third deposition gas used in the third deposition process may further include a carrier gas.

In one or more implementations, which can be combined with other implementations the first undoped semiconductor layer 304 is formed by continuing the flow of the silicon-containing precursor from the second deposition gas while commencing the flow of the n-type carrier dopant, for example, arsenic or antimony dopant gas.

In the third deposition process of operation 650, the cap layer 206 may include an epitaxial portion 206E and an amorphous portion 206A due to different nucleation rates of the cap layer 206 on a surface of the epitaxial portion 304E of the first undoped semiconductor layer 304 and a surface of the amorphous portion 304A of the first undoped semiconductor layer 304. The nucleation may occur at a faster rate on the surface of the epitaxial portion 304E of the first undoped semiconductor layer 304 than on the surface of the amorphous portion 304A of the first undoped semiconductor layer 304, and thus an epitaxial portion 206E of the cap layer 206 may be formed selectively on the surface of the epitaxial portion 304E of the first undoped semiconductor layer 304 while an amorphous portion 206A of the cap layer 206 may be formed on the surface of the amorphous portion 304A of the first undoped semiconductor layer 304. The amorphous portion 206A of the cap layer 206 may be removed in the subsequent etch process performed during operation 670.

Referring to FIG. 7D, at operation 660, subsequent to the third deposition process, a fourth deposition process may be performed for form a second undoped semiconductor layer 704 on the cap layer 206. The fourth deposition process may include any suitable deposition technique, such as epitaxial (Epi) deposition, chemical vapor deposition (CVD), atomic layer deposition (ALD), or physical vapor deposition (PVD), by flowing a deposition gas in a processing chamber, such as the deposition chamber 100 shown in FIG. 1. In one or more implementations, which can be combined with other implementations, the fourth deposition process is an epitaxial deposition process.

The second undoped semiconductor layer 704 is formed of silicon (Si) or silicon germanium (SiGe) with a ratio of germanium (Ge) ranging between 1% and 100%, for example, a ratio of Ge ranging between 1% and 10%. The deposition gas used in the fourth deposition process may be similar to the deposition gas used in the second deposition process of operation 640. The fourth deposition gas used in the fourth deposition process may further include a carrier gas.

In one or more implementations, which can be combined with other implementations, the fourth deposition gas used in the fourth deposition process includes only the silicon-containing precursor, the germanium-containing precursor, or a combination thereof. Thus, the deposition gas does not include a dopant source.

In one or more implementations, which can be combined with other implementations the second undoped semiconductor layer 704 is formed by continuing the flow of the silicon-containing precursor from the third deposition gas while ceasing the flow of the antimony or arsenic dopant used in the third deposition gas.

In the fourth deposition process of operation 660, the second undoped semiconductor layer 704, as deposited, may include an epitaxial portion 704E and an amorphous portion 704A, due to, for example, different nucleation rates of the second undoped semiconductor layer 704 on a surface of the underlying epitaxial portion 206E₁ and a surface of the amorphous portion 206A of the cap layer 206. The nucleation may occur at a faster rate on the surface of the epitaxial portion 206E of the cap layer 206 than on the surface of the amorphous portion 206A of the cap layer 206, and thus an epitaxial portion 704E of the second undoped semiconductor layer 704 may be formed selectively on the surface of the epitaxial portion 206E of the cap layer 206 while an amorphous portion 704A of the second undoped semiconductor layer 704 may be formed on the surface of the amorphous portion 206A of the cap layer 206. The amorphous portion 704A of the second undoped semiconductor layer 704 may be removed in the subsequent etch process performed during operation 670.

Referring to FIG. 7E, at operation 670, an etch process is performed to remove an amorphous portion 704A of the second undoped semiconductor layer 704 (if present), the amorphous portion 206A of the underlying cap layer 206, the amorphous portion 304A of the first undoped semiconductor layer 304, and the underlying amorphous portion 204A of the doped semiconductor layer 204. The etch process in operation 670 may be performed, by flowing an etching gas in the processing chamber, subsequent to the fourth deposition process of operation 660 (if performed) or the third deposition process of operation 650, or simultaneously with the first deposition process of operation 630, the second deposition process of operation 640, the third deposition process of operation 650, and/or the fourth deposition process of operation 660.

In the etch process of operation 670, the amorphous portion 704A of the second undoped semiconductor layer 704 can be etched at a faster rate than the epitaxial portion 704E of the second undoped semiconductor layer 704, by an appropriate etching gas, and the epitaxial portion 704E of the second undoped semiconductor layer 704 may be mostly left un-etched, as shown in FIG. 7E. Etch selectivity between the amorphous portion 704A and the epitaxial portion 704E of the second undoped semiconductor layer 704 is greater than the etch selectivity between the epitaxial portion 204E₁ and the amorphous portion 204A of the doped semiconductor layer 204. The underlying amorphous portion 204A of the doped semiconductor layer 204 can be further etched by using the epitaxial portions 304E, 206E, and/or 704E as a mask, and the epitaxial portion 204E of the doped semiconductor layer 204 is left un-etched, as shown in FIG. 7E. Thus, an overall result of the epitaxial deposition process and the etch process combined can be growth of the epitaxial portion 204E of the doped semiconductor layer 204 (also referred to as the “doped semiconductor epitaxial layer”), the epitaxial portion 304E of the first undoped semiconductor layer 304, the epitaxial portion 206E of the cap layer 206 (also referred to as the “cap epitaxial layer”), and optionally the epitaxial portion 704E of the second undoped semiconductor layer 704 on the device substrate 202.

In some implementations where the second undoped semiconductor layer 704 is present, the amorphous portion 704A of the second undoped semiconductor layer 704 is etched at a faster rate than the epitaxial portion 704E of the second undoped semiconductor layer 704. In some implementations, both the amorphous portion 704A and the epitaxial portion 704E of the second undoped semiconductor layer 704 are removed during the etching process of operation 670. In other implementations, at least a portion of the epitaxial portion 704E of the second undoped semiconductor layer 704 remains while the amorphous portion 704A is completely removed as is shown in FIG. 7E.

The etching gas used in the etch process of operation 670 includes an etchant gas and may further include a carrier gas. The etchant gas may include halogen-containing gas, such as hydrogen chloride (HCl), chlorine (Cl₂), or hydrogen fluoride (HF). The carrier gas may include nitrogen (N₂), argon (Ar), helium (He), or hydrogen (H₂).

A cycle of the phosphorous soak of operation 620, the first deposition process of operation 630, the second deposition process of operation 640, the third deposition process of operation 650, the optional fourth deposition process of operation 660, and the etch process of operation 670 may be repeated as a plurality of cycles, as needed to obtain a targeted combined thickness of the epitaxial portions 204E of the doped semiconductor layers 204 and the overlying epitaxial portion 304E, the epitaxial portion 206E, and optional epitaxial portion 704E in a range from about 10 Å to about 1,000 Å, or in a range from about 100 Å to 700 Å, for example, about 600 Å. The cycle may be repeated, for example, about 30 times.

The previously described implementations of the present disclosure have many advantages, including the following. The deposition method described has improved throughput compared to conventional cyclic deposition and etch processes. The process described is more compatible with various chambers in mass production. The ability to retard phosphorous diffusion into adjacent layers enables deposition of an epitaxial film with a high level of dopant, for example, an a phosphorous dopant concentration of greater than 3×10²¹ atoms per cubic centimeter, which is beneficial for resistivity tuning. The improved etch selectively of the process described widens the process window tuning, thus increasing adaptability and feasibility. The improved selectively of the selective epitaxial deposition process described widens the process window tuning, thus increasing adaptability and feasibility. However, the present disclosure does not necessitate that all the advantageous features and all the advantages need to be incorporated into every implementation of the present disclosure.

In the Summary and in the Detailed Description, and the Claims, and in the accompanying drawings, reference is made to particular features (including method operations) of the present disclosure. It is to be understood that the disclosure in this specification includes all possible combinations of such particular features. For example, where a particular feature is disclosed in the context of a particular aspect, implementation, implementation, or example of the present disclosure, or a particular claim, that feature can also be used, to the extent possible in combination with and/or in the context of other particular aspects and implementations of the present disclosure, and in the present disclosure generally.

Implementations and all of the functional operations described in this specification can be implemented in digital electronic circuitry, or in computer software, firmware, or hardware, including the structural means disclosed in this specification and structural equivalents thereof, or in combinations of them. Implementations described herein can be implemented as one or more non-transitory computer program products, i.e., one or more computer programs tangibly embodied in a machine readable storage device, for execution by, or to control the operation of, data processing apparatus, e.g., a programmable processor, a computer, or multiple processors or computers.

The processes and logic flows described in this specification can be performed by one or more programmable processors executing one or more computer programs to perform functions by operating on input data and generating output. The processes and logic flows can also be performed by, and apparatus can also be implemented as, special purpose logic circuitry, e.g., an FPGA (field programmable gate array) or an ASIC (application specific integrated circuit).

The term “data processing apparatus” encompasses all apparatus, devices, and machines for processing data, including by way of example a programmable processor, a computer, or multiple processors or computers. The apparatus can include, in addition to hardware, code that creates an execution environment for the computer program in question, e.g., code that constitutes processor firmware, a protocol stack, a database management system, an operating system, or a combination of one or more of them. Processors suitable for the execution of a computer program include, by way of example, both general and special purpose microprocessors, and any one or more processors of any kind of digital computer.

Computer readable media suitable for storing computer program instructions and data include all forms of nonvolatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

The term “comprises” and grammatical equivalents thereof are used herein to mean that other components, ingredients, operations, etc. are optionally present. For example, an article “comprising” (or “which comprises”) components A, B, and C can consist of (i.e., contain only) components A, B, and C, or can contain not only components A, B, and C but also one or more other components. In addition, whenever a composition, an element or a group of elements is preceded with the transitional phrase “comprising” or grammatical equivalents thereof, it is understood that it is contemplated that the same composition or group of elements may be preceded with transitional phrases “consisting essentially of,” “consisting of,” “selected from the group of consisting of,” or “is” preceding the recitation of the composition, element, or elements and vice versa.

Where reference is made herein to a method comprising two or more defined operations, the defined operations can be carried out in any order or simultaneously (except where the context excludes that possibility), and the method can include one or more other operations which are carried out before any of the defined operations, between two of the defined operations, or after all of the defined operations (except where the context excludes that possibility).

When introducing elements of the present disclosure or exemplary aspects or implementation(s) thereof, the articles “a,” “an,” “the” and “said” are intended to mean that there are one or more of the elements.

The terms “comprising,” “including” and “having” are intended to be inclusive and mean that there may be additional elements other than the listed elements.

While the foregoing is directed to implementations of the present disclosure, other and further implementations of the disclosure may be devised without departing from the basic scope thereof, and the scope thereof is determined by the claims that follow.

What is claimed is:

1. A method of forming a doped semiconductor layer in a semiconductor structure, comprising:
performing a first deposition process, a second deposition process subsequent to the first deposition process, and an etch process,
the first deposition process forming an n-type doped semiconductor layer comprising a first n-type dopant on an exposed surface of a substrate;
the second deposition process forming an n-type doped capping layer on the doped semiconductor layer, the n-type doped capping layer comprising a second n-type dopant different from the first n-type dopant; and
the etch process selectively removing an amorphous portion of the n-type doped semiconductor layer and an amorphous portion of the n-type doped capping layer, and leaving an epitaxial portion of the n-type doped semiconductor layer, wherein
the n-type doped semiconductor layer and the n-type doped capping layer comprise silicon.

2. The method of claim 1, wherein the first n-type dopant comprises phosphorus.

3. The method of claim 2, wherein the second n-type dopant comprises arsenic, antimony, or both arsenic and antimony.

4. The method of claim 1, wherein the first deposition process comprises flowing a silicon-containing precursor in a processing chamber.

5. The method of claim 4, wherein the second deposition process comprises flowing the silicon-containing precursor and a second n-type dopant source in the processing chamber.

6. The method of claim 5, wherein the etch process comprises flowing an etchant gas and a carrier gas in a processing gas, subsequent to the second deposition process.

7. The method of claim 6, wherein the first deposition process and the second deposition process are performed at a temperature less than about 500 degrees Celsius and at a pressure in a range from about 10 Torr about 50 Torr.

8. The method of claim 1, wherein the exposed surface of the substrate comprises one or more monocrystalline surfaces and one or more non-monocrystalline surfaces, the epitaxial portion of the n-type doped semiconductor layer selectively formed on the one or more monocrystalline surfaces and the amorphous portion of the n-type doped semiconductor layer formed on the one or more non-monocrystalline surfaces.

9. The method of claim 1, further comprising a third deposition process performed subsequent to the second deposition process, the third deposition process forming an undoped semiconductor layer on the n-type doped capping layer.

10. A semiconductor structure, comprising:
a stack of alternating doped semiconductor epitaxial layers and cap epitaxial layers formed on a substrate, wherein
each doped semiconductor epitaxial layer comprises silicon having a first n-type dopant, and
each cap epitaxial layer comprises silicon having a second n-type dopant different from the first n-type dopant.

11. The semiconductor structure of claim 10, wherein the first n-type dopant comprises phosphorous.

12. The semiconductor structure of claim 11, wherein the second n-type dopant comprises arsenic, antimony, or both arsenic and antimony.

13. The semiconductor structure of claim 12, wherein the stack of alternating doped semiconductor epitaxial layers and cap epitaxial layers have a thickness in a range from about 10 Å to about 1,000 Å.

14. A processing system, comprising:
a processing chamber; and
a system controller configured to cause the processing system to:
performing a first deposition process, a second deposition process subsequent to the first deposition process, and an etch process,
the first deposition process forming an n-type doped semiconductor layer comprising a first n-type dopant on an exposed surface of a substrate;
the second deposition process forming an n-type doped capping layer on the n-type doped semiconductor layer, the n-type doped capping layer comprising a second n-type dopant different from the first n-type dopant; and
the etch process selectively removing an amorphous portion of the n-type doped semiconductor layer and an amorphous portion of the n-type doped capping layer, and leaving an epitaxial portion of the n-type doped semiconductor layer, wherein
the n-type doped semiconductor layer and the n-type doped capping layer comprise silicon.

15. The processing system of claim 14, wherein the first n-type dopant comprises phosphorus.

16. The processing system of claim 15, wherein the first deposition process comprises flowing a silicon-containing precursor in the processing chamber.

17. The processing system of claim 16, wherein the second deposition process comprises flowing the silicon-containing precursor and a second n-type dopant source in the processing chamber.

18. The processing system of claim 17, wherein the etch process comprises flowing an etchant gas and a carrier gas in a processing gas, subsequent to the second deposition process.

19. The processing system of claim 18, wherein the first deposition process and the second deposition process are performed at a temperature less than about 500 degrees Celsius and at a pressure in a range from about 10 Torr about 50 Torr.

20. The processing system of claim 14, wherein the exposed surface of the substrate comprises one or more monocrystalline surfaces and one or more non-monocrystalline surfaces, the epitaxial portion of the n-type doped semiconductor layer selectively formed on the one or more monocrystalline surfaces and the amorphous portion of the n-type doped semiconductor layer formed on the one or more non-monocrystalline surfaces.
